(19) United States
(12) Patent Application Publication
(10) Pub. No.: US 2010/0289588 A1
(43) Pub. Date: Nov. 18, 2010

(54) OSCILLATOR CIRCUIT

(75) Inventor: Yuji Satoh, Tokyo (JP)

Correspondence Address: TUROCY & WATSON, LLP, 127 Public Square, 57th Floor, Key Tower, CLEVELAND, OH, 44114, US

(73) Assignee: KABUSHIKI KAISHA TOSHIBA, Tokyo (JP)

(21) Appl. No.: 12/603,798

(22) Filed: Oct. 22, 2009

(30) Foreign Application Priority Data
May 18, 2009 (JP) 2009-119692

(51) Int. Cl. H03K 3/03

(52) U.S. Cl. 331/57; 331/117 FE

(57) ABSTRACT

An oscillator circuit includes an oscillator that generates an oscillation signal and a limiter that limits amplitude of the oscillation signal output from the oscillator.

### CROSS-REFERENCE TO RELATED APPLICATIONS

This application is based upon and claims the benefit of priority from the prior Japanese Patent Application No. 2009-119692, filed on May 18, 2009; the entire contents of which are incorporated herein by reference.

### BACKGROUND OF THE INVENTION

1. Field of the Invention

The present invention relates to an oscillator circuit, and is particularly suitable for applying to a method of reducing a frequency fluctuation of an oscillation waveform output from an oscillator circuit formed on a semiconductor integrated circuit.

2. Description of the Related Art

With a voltage reduction in an operation of a semiconductor integrated circuit, amplitude of an oscillation waveform output from an oscillator circuit formed on the semiconductor integrated circuit has become small. Therefore, an oscillation frequency of an oscillator circuit formed on a semiconductor integrated circuit is easily affected by a fluctuation in power-supply voltage or temperature.

For example, Japanese Patent Application Laid-open No. H11-154849 discloses a method of controlling amplitude of a sawtooth waveform to be constant in a specific frequency range of a preset signal, in which the sawtooth waveform having a desired slope is output based on a signal having an arbitrary frequency and the amplitude of the sawtooth waveform is limited in a frequency equal to or lower than the specific frequency of the signal.

However, in the method disclosed in Japanese Patent Application Laid-open No. H11-154849, although the amplitude of the sawtooth waveform can be made constant by limiting the amplitude of the sawtooth waveform, the oscillation frequency cannot be made constant by causing the amplitude of the sawtooth waveform to be constant.

### BRIEF SUMMARY OF THE INVENTION

An oscillator circuit according to an embodiment of the present invention comprises: an oscillator that generates an oscillation signal; and a limiter that limits amplitude of the oscillation signal output from the oscillator.

An oscillator circuit according to an embodiment of the present invention comprises: a ring oscillator that generates an oscillation signal; a limiter that limits amplitude of an oscillation output for one stage of the ring oscillator; and a current control circuit that controls a bias current of remaining stages of the ring oscillator based on the oscillation output of which amplitude is limited by the limiter.

An oscillator circuit according to an embodiment of the present invention comprises: an oscillator that generates a plurality of oscillation signals; and a limiter that limits amplitude of at least one of the oscillation signals.

### BRIEF DESCRIPTION OF THE DRAWINGS

FIG. 1 is a block diagram illustrating a schematic configuration of an oscillator circuit according to a first embodiment of the present invention;

FIG. 2 is a schematic diagram illustrating a comparison between an oscillation waveform limited in the oscillator circuit shown in FIG. 1 and an oscillation waveform not limited in the oscillator circuit shown in FIG. 1;

FIG. 3 is a circuit diagram illustrating a circuit configuration of an oscillator circuit according to a second embodiment of the present invention;

FIG. 4 is a circuit diagram illustrating a circuit configuration of an oscillator circuit according to a third embodiment of the present invention;

FIG. 5 is a circuit diagram illustrating a circuit configuration of an oscillator circuit according to a fourth embodiment of the present invention; and

FIG. 6 is a circuit diagram illustrating a circuit configuration of an oscillator circuit according to a fifth embodiment of the present invention.

### DETAILED DESCRIPTION OF THE INVENTION

Exemplary embodiments of an oscillator circuit according to the present invention are described in detail below with reference to the accompanying drawings. The present invention is not limited to the embodiments.

### First Embodiment

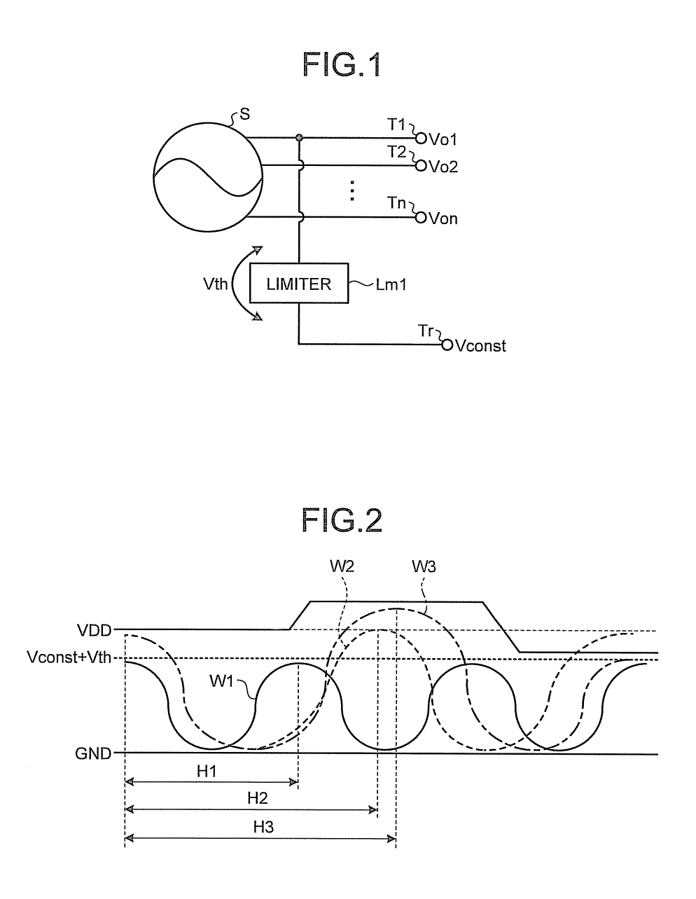

FIG. 1 is a block diagram illustrating a schematic configuration of an oscillator circuit according to the first embodiment of the present invention.

The oscillator circuit includes an oscillator S and a limiter Lm1. The oscillator S and the limiter Lm1 can be formed on a semiconductor integrated circuit. The oscillator S can generate oscillation signals Vo1 to Von (n is a positive integer). The oscillator S can be, for example, a ring oscillator, an RC oscillator such as an Wien bridge oscillator, a tunable oscillator, an LC back-coupling oscillator, or a multivibrator. The oscillator S is provided with output terminals T1 to Tn from which the oscillation signals Vo1 to Von are output, respectively.

The limiter Lm1 can limit the amplitude of at least one of the oscillation signals Vo1 to Von from the output terminals T1 to Tn of the oscillator S. The limiter Lm1 is provided with a reference voltage input terminal Tr to which a reference voltage Vconst is input. For example, in the case of limiting the amplitude of the oscillation signal Vo1 of the output terminal T1, the limiter Lm1 compares the voltage of the oscillation signal Vo1 with the value that is obtained by adding a voltage drop Vth in the limiter Lm1 to the reference voltage Vconst. When the voltage of the oscillation signal Vo1 exceeds the value obtained by adding the voltage drop Vth to the reference voltage Vconst, the amplitude of the oscillation signal Vo1 is set to the value obtained by adding the voltage drop Vth to the reference voltage Vconst.

Therefore, even when there is a fluctuation in power-supply voltage of a semiconductor integrated circuit or temperature, it is possible to keep the amplitude of the oscillation waveform constant, enabling to reduce the frequency fluctuation of the oscillation waveform. Thus, even if a semiconductor integrated circuit is operated at low voltage, the accuracy of the oscillation frequency can be improved without using a crystal oscillator, so that an external component need not be provided, enabling to reduce power consumption of the oscillator circuit.

Consequently, a counting operation can be performed in high accuracy even in the low-power consumption mode of the Bluetooth or the like which is used in a short-distance wireless communication or the like, enabling to effectively be applied to a process of judging a transmission/reception stop period or the like.

In order to suppress increase in power consumption of the oscillator circuit and make a parasitic effect component of a field-effect transistor disappear, the oscillation frequency of the oscillation signals Vo1 to Von is preferably 1 MHz or less.

In the above present embodiment, the method is explained to limit the amplitude of the output of the output terminal T1 out of the output terminals T1 to Tn of the oscillator S; however, the amplitude of the output of at least one of the output terminals T1 to Tn can be limited. Alternatively, the amplitude of the outputs of all of the output terminals T1 to Tn can be limited.

FIG. 2 is a schematic diagram illustrating an oscillation waveform limited in the oscillator circuit shown in FIG. 1 and an oscillation waveform not limited in the oscillator circuit shown in FIG. 1.

In FIG. 2, the power-supply voltage of the oscillator S is denoted by VDD. When the amplitude is not limited by the limiter Lm1, the oscillation waveform of the oscillator S becomes one like an oscillation waveform W2 and the amplitude fluctuates between the power-supply voltage VDD and a ground voltage GND, so that the amplitude of the oscillation waveform W2 is determined by a potential difference Va between the power-supply voltage VDD and the ground voltage GND.

Then, when the power-supply voltage VDD fluctuates, the oscillation waveform of the oscillator S is changed from the oscillation waveform W2 to an oscillation waveform W3, and the amplitude of the oscillator S also fluctuates along with the fluctuation of the power-supply voltage VDD. The period of the oscillator S is determined based on the amplitude of the oscillation waveform. When the oscillation waveform of the oscillator S is changed from the oscillation waveform W2 to the oscillation waveform W3, the period of the oscillator S is also changed from a period H2 to a period H3, so that the oscillation frequency of the oscillator S changes.

Specifically, a period T of the oscillator S is approximately given by Equation (1):

T=2C1·Va/Is (1)

where Is is a bias current of the oscillator S and C1 is a load capacitance.

When the amplitude of the oscillation signal Vo1 is limited by the limiter Lm1 shown in FIG. 1, the amplitude of the oscillation signal Vo1 is limited to the value obtained by adding the voltage drop Vth to the reference voltage Vconst, and the oscillation waveform of the oscillation signal Vo1 becomes one like an oscillation waveform W1. Therefore, even when the power-supply voltage VDD fluctuates, the amplitude of the oscillation signal Vo1 is prevented from fluctuating and a period H1 of the oscillation waveform W1 is kept constant, so that the oscillation frequency of the oscillator S can be prevented from changing.

### Second Embodiment

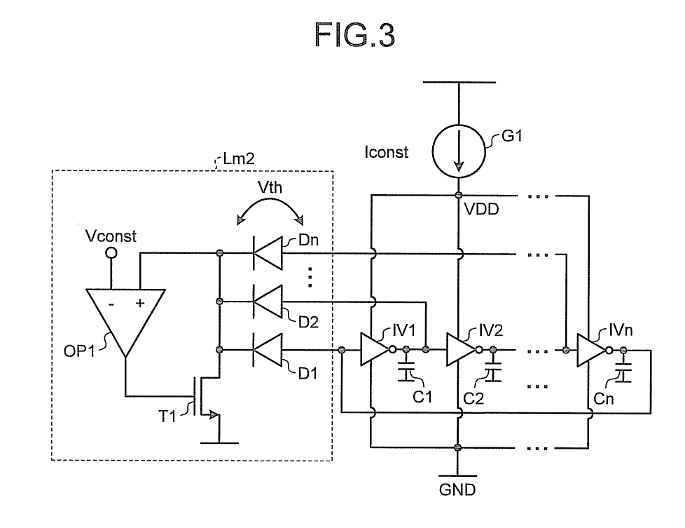

FIG. 3 is a circuit diagram illustrating a circuit configuration of an oscillator circuit according to the second embodiment of the present invention.

The oscillator circuit shown in FIG. 3 includes a ring oscillator and a limiter Lm2. The ring oscillator includes inverters IV1 to IVn, and the limier Lm2 includes diodes D1 to Dn, an operational amplifier OP1, and an N-channel field-effect transistor (hereinafter, Nch transistor) T1. The inverters IV1 to IVn are provided with load capacitors C1 to Cn, respectively. The load capacitors C1 to Cn can be, for example, a metal oxide metal (MOM) capacitor. A line itself can act as the MOM capacitor.

The inverters IV1 to IVn are sequentially connected in series, and the output of the inverter IVn on the last stage is connected to the input of the inverter IV1 on the first stage, thereby configuring the ring oscillator. When configuring the ring oscillator with the inverters IV1 to IVn, the number of the stages of the inverters IV1 to IVn can be set to an odd number. A constant current source G1 as a current source that supplies a bias current of the inverters IV1 to IVn is connected on the side of the VDD. The oscillation frequency of the ring oscillator can be determined based on the current value of the constant current source G1 and the values of the load capacitors C1 to Cn.

The input terminals of the inverters IV1 to IVn are connected to the drain of the Nch transistor T1 and the non-inverting input terminal of the operational amplifier OP1 via the diodes D1 to Dn. The forward drop voltage of the diodes D1 to Dn can be set to the Vth. The diodes D1 to Dn can be formed by a PN junction or by a field-effect transistor in which a drain is connected to a gate.

The reference voltage Vconst is input to the inverting input terminal of the operational amplifier OP1, and the output terminal of the operational amplifier OP1 is connected to the gate of the Nch transistor T1. The reference voltage Vconst can be set, for example, within the range of 0.2 V to 0.3 V. A band gap reference voltage can be used as the reference voltage Vconst.

A bias current Iconst is supplied from the constant current source G1 to each of the inverters IV1 to IVn. Then, the input voltage of each stage of the inverters IV1 to IVn is applied to the non-inverting input terminal of the operational amplifier OP1 via a corresponding one of the diodes D1 to Dn to be compared with the reference voltage Vconst. When the input voltage of each stage of the inverters IV1 to IVn exceeds the value obtained by adding the forward drop voltage Vth of the diodes D1 to Dn to the reference voltage Vconst, the potential of the output terminal of the operational amplifier OP1 becomes a high level, so that the Nch transistor T1 is turned on.

The Nch transistor T1 is turned on, so that even when the input voltage of each stage of the inverters IV1 to IVn exceeds the value obtained by adding the forward drop voltage Vth of the diodes D1 to Dn to the reference voltage Vconst, the potential of the diodes D1 to Dn on the cathode side is kept to match the reference voltage Vconst. Therefore, the input voltage of each stage of the inverters IV1 to IVn is limited to the value obtained by adding the forward drop voltage Vth of the diodes D1 to Dn to the reference voltage Vconst.

The amplitude of the input voltage of the ring oscillator is limited, so that even if there is a fluctuation in the power-supply voltage VDD of the ring oscillator or temperature, it is possible to keep the amplitude of the oscillation waveform of the ring oscillator constant, enabling to reduce the frequency fluctuation of the oscillation waveform while suppressing increase in power consumption.

In the above embodiment, the method is explained to use the inverters IV1 to IVn to configure the ring oscillator; however, the ring oscillator can be configured with an inverting logic circuit such as a NAND circuit or a NOR circuit.

### Third Embodiment

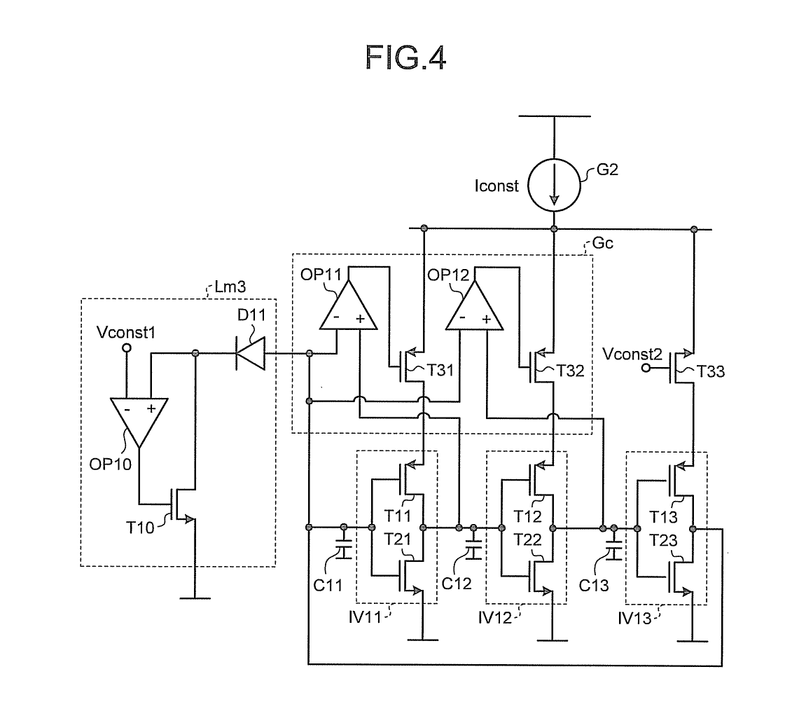

FIG. 4 is a circuit diagram illustrating a circuit configuration of an oscillator circuit according to the third embodiment of the present invention.

The oscillator circuit shown in FIG. 4 includes a ring oscillator, a limiter Lm3, a current control circuit Gc, and a constant current source G2. The ring oscillator includes inverters IV11 to IV13, and the limier Lm3 includes a diode D11, an operational amplifier OP10, and an Nch transistor T10. The current control circuit Gc includes operational amplifiers OP11 and OP 12 and P-channel field-effect transistors (hereinafter, Pch transistor) T31 and T32. The inverters IV11 to IV13 are provided with load capacitors C11 to C13, respectively.

The inverters IV11 to IV13 are sequentially connected in series, and the output of the inverter IV13 on the last stage is connected to the input of the inverter IV11 on the first stage, thereby configuring the ring oscillator.

The inverter IV11 includes a Pch transistor T11 and an Nch transistor T21, the inverter IV12 includes a Pch transistor T12 and an Nch transistor T22, and the inverter IV13 includes a Pch transistor T13 and an Nch transistor T23.

The drain of the Pch transistor T11 and the drain of the Nch transistor T21 are commonly connected to the gate of the Pch transistor T12 and the gate of the Nch transistor T22. The drain of the Pch transistor T12 and the drain of the Nch transistor T22 are commonly connected to the gate of the Pch transistor T13 and the gate of the Nch transistor T23. The drain of the Pch transistor T13 and the drain of the Nch transistor T23 are commonly connected to the gate of the Pch transistor T11 and the gate of the Nch transistor T21.

The source of the Pch transistor T11 is connected to the drain of the Pch transistor T31. The source of the Pch transistor T12 is connected to the drain of the Pch transistor T32. The source of the Pch transistor T13 is connected to the drain of an Nch transistor T33. The sources of the Pch transistors T31 and T32 and the source of the Nch transistor T33 are connected to the constant current source G2.

The gate of the Pch transistor T11 and the gate of the Nch transistor T21 are connected to the drain of the Nch transistor T10 and the non-inverting input terminal of the operational amplifier OP10 via the diode D11. The forward drop voltage of the diode D11 can be set to the Vth. The diode D11 can be formed by a PN junction or by a field-effect transistor in which a drain is connected to a gate.

A reference voltage Vconst2 is input to the inverting input terminal of the operational amplifier OP10 and the gate of the Nch transistor T33, and the output terminal of the operational amplifier OP10 is connected to the gate of the Nch transistor T10.

The gate of the Pch transistor T11 and the gate of the Nch transistor T21 are connected to the inverting input terminals of the operational amplifiers OP11 and OP12. The gate of the Pch transistor T12 and the gate of the Nch transistor T22 are connected to the non-inverting input terminal of the operational amplifier OP11. The gate of the Pch transistor T13 and the gate of the Nch transistor T23 are connected to the non-inverting input terminal of the operational amplifier OP12.

The output terminal of the operational amplifier OP11 is connected to the gate of the Pch transistor T31, and the output terminal of the operational amplifier OP12 is connected to the gate of the Pch transistor T32.

A bias current is supplied to the inverter IV11 via the Pch transistor T31, a bias current is supplied to the inverter IV12 via the Pch transistor T32, and a bias current is supplied to the inverter IV13 via the Nch transistor T33. The input voltage of the inverter IV11 is applied to the non-inverting input terminal of the operational amplifier OP10 via the diode D11 to be compared with a reference voltage Vconst1.

Then, when the input voltage of the inverter IV11 exceeds the value obtained by adding the forward drop voltage Vth of the diode D11 to the reference voltage Vconst1, the potential of the output terminal of the operational amplifier OP10 becomes a high level, so that the Nch transistor T10 is turned on.

The Nch transistor T10 is turned on, so that even when the input voltage of the inverter IV11 exceeds the value obtained by adding the forward drop voltage Vth of the diode D11 to the reference voltage Vconst1, the potential of the diode D11 on the cathode side is kept to match the reference voltage Vconst1. Therefore, the input voltage of the inverter IV11 is limited to the value obtained by adding the forward drop voltage Vth of the diode D11 to the reference voltage Vconst1.

The input voltage of the inverter IV12 is compared with the input voltage of the inverter IV11 in the operational amplifier OP11. When the input voltage of the inverter IV12 becomes larger than the input voltage of the inverter IV11, the output level of the operational amplifier OP11 increases. Then, the bias current to be supplied to the inverter IV11 via the Pch transistor T31 decreases, so that the input voltage of the inverter IV12 is kept to match the input voltage of the inverter IV11. Therefore, the input voltage of the inverter IV12 is limited to the value obtained by adding the forward drop voltage Vth of the diode D11 to the reference voltage Vconst1.

The input voltage of the inverter IV13 is compared with the input voltage of the inverter IV11 in the operational amplifier OP12. When the input voltage of the inverter IV13 becomes larger than the input voltage of the inverter IV11, the output level of the operational amplifier OP12 increases. Then, the bias current to be supplied to the inverter IV12 via the Pch transistor T32 decreases, so that the input voltage of the inverter IV13 is kept to match the input voltage of the inverter IV11. Therefore, the input voltage of the inverter IV13 is limited to the value obtained by adding the forward drop voltage Vth of the diode D11 to the reference voltage Vconst1.

Consequently, even when the amplitude of the input voltage of only the inverter IV11 is limited, the amplitude of the oscillation waveform of the ring oscillator can be kept constant, so that the frequency fluctuation of the oscillation waveform can be reduced while suppressing increase in power consumption.

In the above embodiment, the method is explained to use the inverters IV11 to IV13 to configure the ring oscillator; however, the ring oscillator can be configured with an inverting logic circuit such as a NAND circuit or a NOR circuit.

Moreover, in the above embodiment, the method is explained to configure the ring oscillator with the inverters IV11 to IV13 of three stages; however, the number of the inverters can be any arbitrary number so long as it is three or more odd number.

### Fourth Embodiment

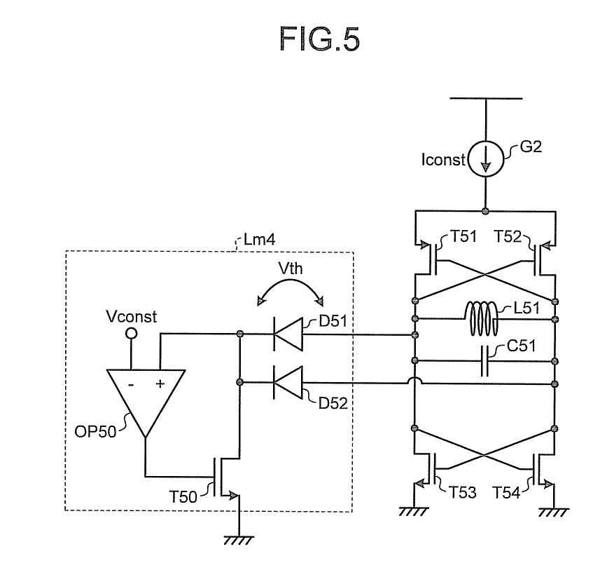

FIG. 5 is a circuit diagram illustrating a circuit configuration of an oscillator circuit according to the fourth embodiment of the present invention.

The oscillator circuit shown in FIG. 5 includes an LC back-coupling oscillator and a limiter Lm4. The LC back-coupling oscillator includes Pch transistors T51 and T52, Nch transistors T53 and T54, a coil L51, and a capacitor C51. The limiter Lm4 includes diodes D51 and D52, an operational amplifier OP50, and an Nch transistor T50.

The gate of the Pch transistor T51 is connected to the drain of the Pch transistor T52, and the gate of the Pch transistor T52 is connected to the drain of the Pch transistor T51 to be cross-coupled.

The gate of the Nch transistor T53 is connected to the drain of the Nch transistor T54, and the gate of the Nch transistor T54 is connected to the drain of the Nch transistor T53 to be cross-coupled.

The source of the Pch transistor T51 and the source of the Pch transistor T52 are connected to the constant current source G2. The drain of the Pch transistor T51 is connected to the drain of the Nch transistor T53, and the drain of the Pch transistor T52 is connected to the drain of the Nch transistor T54.

The coil L51 and the capacitor C51 are connected in parallel between the drain of the Pch transistor T51 and the drain of the Pch transistor T52.

The drain of the Pch transistor T51 and the drain of the Pch transistor T52 are connected to the drain of the Nch transistor T50 and the non-inverting input terminal of the operational amplifier OP50 via the diodes D51 and D52. The forward drop voltage of the diodes D51 and D52 can be set to the Vth. The diodes D51 and D52 can be formed by a PN junction or by a field-effect transistor in which a drain is connected to a gate.

The reference voltage Vconst is input to the inverting input terminal of the operational amplifier OP50, and the output terminal of the operational amplifier OP50 is connected to the gate of the Nch transistor T50.

The bias current Iconst is supplied from the constant current source G2 to the source of the Pch transistor T51 and the source of the Pch transistor T52, and an oscillation signal is output from each of the drain of the Pch transistor T51 and the drain of the Pch transistor T52. Then, the drain voltage of the Pch transistor T51 and the drain voltage of the Pch transistor T52 are applied to the non-inverting input terminal of the operational amplifier OP50 via the diodes D51 and D52, respectively, to be compared with the reference voltage Vconst.

Then, when the drain voltage of the Pch transistor T51 and the drain voltage of the Pch transistor T52 exceed the value obtained by adding the forward drop voltage Vth of the diodes D51 and D52 to the reference voltage Vconst, the potential of the output terminal of the operational amplifier OP50 becomes a high level, so that the Nch transistor T50 is turned on.

The Nch transistor T50 is turned on, so that even when the drain voltage of the Pch transistor T51 and the drain voltage of the Pch transistor T52 exceed the value obtained by adding the forward drop voltage Vth of the diodes D51 and D52 to the reference voltage Vconst, the potential of the diodes D51 to D52 on the cathode side can be kept to match the reference voltage Vconst. The Nch transistor T50 is turned on, so that the drain voltage of the Pch transistor T51 and the drain voltage of the Pch transistor T52 are limited to the value obtained by adding the forward drop voltage Vth of the diodes D51 to D52 to the reference voltage Vconst.

The amplitude of the oscillation signal of the LC back-coupling oscillator is limited, so that even when there is a fluctuation in the power-supply voltage of the LC back-coupling oscillator or temperature, it is possible to keep the amplitude of the oscillation signal of the LC back-coupling oscillator constant, enabling to reduce the frequency fluctuation of the oscillation signal while suppressing increase in power consumption.

In the above embodiment, the method is explained to use the parallel circuit of the coil L51 and the capacitor C51 to configure the LC back-coupling oscillator; however, it is possible to use a Hartley oscillator, a Colpitts oscillator, or the like as the LC back-coupling oscillator.

### Fifth Embodiment

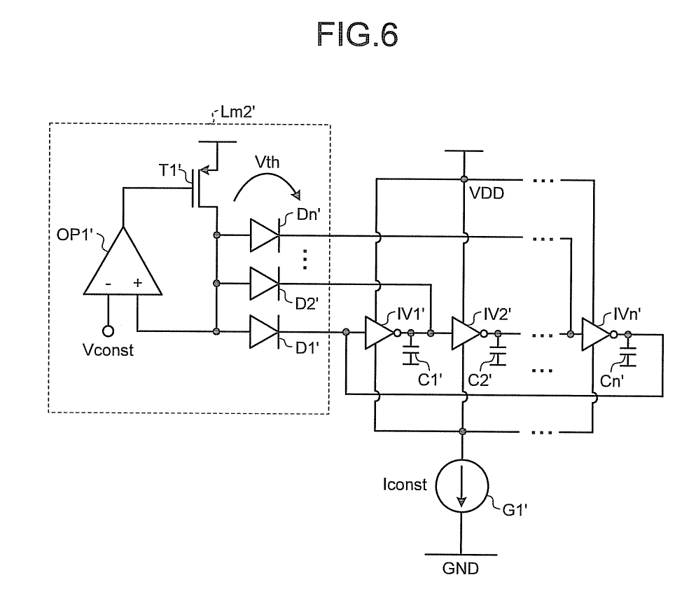

FIG. 6 is a circuit diagram illustrating a circuit configuration of an oscillator circuit according to the fifth embodiment of the present invention.

The oscillator circuit shown in FIG. 6 includes a ring oscillator and a limiter Lm2′. The ring oscillator includes inverters IV1′ to IVn′, and the limier Lm2′ includes diodes D1′ to Dn′, an operational amplifier OP1′, and a Pch transistor T1′. The inverters IV1′ to IVn′ are provided with load capacitors C1′ to Cn′, respectively.

The inverters IV1′ to IVn′ are sequentially connected in series, and the output of the inverter IVn′ on the last stage is connected to the input of the inverter IV1′ on the first stage, thereby configuring the ring oscillator. When configuring the ring oscillator with the inverters IV1′ to IVn′, the number of the stages of the inverters IV1′ to IVn′ can be set to an odd number. A constant current source G1′ as a current source that supplies a bias current of the inverters IV1′ to IVn′ is connected on the side of the GND.

The drain of the Pch transistor T1′ is connected to the input terminals of the inverters IV1′ to IVn′ via the diodes D1′ to Dn′ and is connected to the non-inverting input terminal of the operational amplifier OP1′. The forward drop voltage of the diodes D1′ to Dn′ can be set to the Vth. The diodes D1′ to Dn′ can be formed by a PN junction or by a field-effect transistor in which a drain is connected to a gate.

The reference voltage Vconst is input to the inverting input terminal of the operational amplifier OP1′, and the output terminal of the operational amplifier OP1′ is connected to the gate of the Pch transistor T1′.

The bias current Iconst is supplied from the constant current source G1′ to each of the inverters IV1′ to IVn′. Then, the drain voltage of the Pch transistor T1′ is applied to the non-inverting input terminal of the operational amplifier OP1′ to be compared with the reference voltage Vconst and is given as the input voltage on each stage of the inverters IV1′ to IVn′ via the diodes D1′ to Dn′.

Then, when the input voltage of each stage of the inverters IV1′ to IVn′ becomes less than the value obtained by subtracting the forward drop voltage Vth of the diodes D1′ to Dn′ from the reference voltage Vconst, the potential of the output terminal of the operational amplifier OP1′ becomes a low level, so that the Pch transistor T1′ is turned on.

The Pch transistor T1′ is turned on, so that even when the input voltage of each stage of the inverters IV1′ to IVn′ becomes less than the value obtained by subtracting the forward drop voltage Vth of the diodes D1′ to Dn′ from the reference voltage Vconst, the potential of the diodes D1′ to Dn′ on the anode side can be kept to match the reference voltage Vconst. Therefore, the input voltage of each stage of the inverters IV1′ to IVn′ is kept to the value obtained by subtracting the forward drop voltage Vth of the diodes D1′ to Dn′ from the reference voltage Vconst.

The amplitude of the input voltage of the ring oscillator is limited, so that even when there is a fluctuation in the voltage of the ring oscillator on the ground side or temperature, it is possible to keep the amplitude of the oscillation waveform of the ring oscillator constant, enabling to reduce the frequency fluctuation of the oscillation waveform while suppressing increase in power consumption.

In the above embodiment, the method is explained to use the inverters IV1′ to IVn′ to configure the ring oscillator; however, the ring oscillator can be configured with an inverting logic circuit such as a NAND circuit or a NOR circuit.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. An oscillator circuit comprising:
an oscillator that generates an oscillation signal; and
a limiter that limits amplitude of the oscillation signal output from the oscillator.

2. The oscillator circuit according to claim 1, wherein an oscillation frequency of the oscillation signal is 1 MHz or less.

3. The oscillator circuit according to claim 1, wherein the oscillator is a ring oscillator.

4. The oscillator circuit according to claim 3, wherein
the limiter includes
an operational amplifier in which a reference voltage is input to an inverting input terminal and an input terminal of each stage of the ring oscillator is connected to a non-inverting input terminal via a diode; and
an N-channel field-effect transistor in which an output terminal of the operational amplifier is connected to a gate and the non-inverting input terminal of the operational amplifier is connected to a drain.

5. The oscillator circuit according to claim 3, wherein
the limiter includes
an operational amplifier in which a reference voltage is input to an inverting input terminal and a non-inverting input terminal is connected to an input terminal of each stage of the ring oscillator via a diode; and
a P-channel field-effect transistor in which an output terminal of the operational amplifier is connected to a gate and the non-inverting input terminal of the operational amplifier is connected to a drain.

6. An oscillator circuit comprising:
a ring oscillator that generates an oscillation signal;
a limiter that limits amplitude of an oscillation output for one stage of the ring oscillator; and
a current control circuit that controls a bias current of remaining stages of the ring oscillator based on the oscillation output of which amplitude is limited by the limiter.

7. The oscillator circuit according to claim 6, wherein
the limiter includes
a first operational amplifier in which a reference voltage is input to an inverting input terminal and the oscillation output for one stage of the ring oscillator is input to a non-inverting input terminal via a diode; and
an N-channel field-effect transistor in which an output terminal of the first operational amplifier is connected to a gate and the non-inverting input terminal of the first operational amplifier is connected to a drain, and
the current control circuit includes
a second operational amplifier that compares the oscillation output input to the first operational amplifier and an oscillation output of the remaining stages of the ring oscillator; and
a P-channel field-effect transistor that adjusts a bias current supplied to the remaining stages of the ring oscillator based on an output from the second operational amplifier.

8. The oscillator circuit according to claim 1, wherein the oscillator is an LC back-coupling oscillator.

9. The oscillator circuit according to claim 8, wherein
the limiter includes
an operational amplifier in which a reference voltage is input to an inverting input terminal and an output terminal of the oscillation signal of the LC back-coupling oscillator is connected to a non-inverting input terminal via a diode; and
an N-channel field-effect transistor in which an output terminal of the operational amplifier is connected to a gate and the non-inverting input terminal of the operational amplifier is connected to a drain.

10. An oscillator circuit comprising:
an oscillator that generates a plurality of oscillation signals; and
a limiter that limits amplitude of at least one of the oscillation signals.

11. The oscillator circuit according to claim 10, wherein the limiter limits to amplitude of a voltage lower than a power-supply voltage supplied to the oscillator.

12. The oscillator circuit according to claim 11, wherein the limiter, when amplitude of an oscillation signal to be controlled exceeds a predetermined value, keeps the amplitude of the oscillation signal to amplitude based on a reference voltage.

13. The oscillator circuit according to claim 11, wherein the limiter, when amplitude of an oscillation signal to be controlled becomes lower than a predetermined value, keeps the amplitude of the oscillation signal to amplitude based on a reference voltage.

14. The oscillator circuit according to claim 10, further comprising a current control circuit that supplies a bias current to the oscillator and controls so that voltages of the oscillation signals match with each other.

15. The oscillator circuit according to claim 14, wherein the limiter limits to amplitude of a voltage lower than a power-supply voltage supplied to the oscillator.

16. The oscillator circuit according to claim 15, wherein the limiter, when amplitude of an oscillation signal to be controlled exceeds a predetermined value, keeps the amplitude of the oscillation signal to amplitude based on a reference voltage.

17. The oscillator circuit according to claim 15, wherein the limiter, when amplitude of an oscillation signal to be controlled becomes lower than a predetermined value, keeps the amplitude of the oscillation signal to amplitude based on a reference voltage.

18. The oscillator circuit according to claim 10, wherein an oscillation frequency of the oscillation signal is 1 MHz or less.
